(19) United States
(12) Patent Application Publication
(10) Pub. No.: US 2014/0183614 A1
(43) Pub. Date: Jul. 3, 2014

(54) SEMICONDUCTOR DEVICE

(71) Applicant: UNITED MICROELECTRONICS CORP., Hsin-Chu City (TW)

(72) Inventors: ZHAOBING LI, Singapore (SG); Cheng-Yuan Hsu, Hsinchu City (TW); CHI REN, Singapore (SG)

(73) Assignee: UNITED MICROELECTRONICS CORP., Hsin-Chu City (TW)

(21) Appl. No.: 13/733,147

(22) Filed: Jan. 3, 2013

(51) Int. Cl. H01L 29/788

(52) U.S. Cl. CPC H01L 29/788
USPC 257/316

(57) ABSTRACT

A semiconductor device is provided. The semiconductor device includes a semiconductor substrate, at least a first gate, a shallow trench isolation (STI) and a third gate. The first gate is disposed on the semiconductor substrate, and the first gate partially overlaps the third gate and the shallow trench isolation. Furthermore, the third gate is disposed in a shallow trench isolation, and the third gate includes at least a protrusion.

### BACKGROUND OF THE INVENTION

1. Field of the Invention

The present invention relates to a semiconductor device, and more particularly to a semiconductor device including a gate disposed in a shallow trench isolation (STI), wherein the gate has at least a protrusion.

2. Description of the Prior Art

A flash memory is a non-volatile memory that can preserve data within the memory even when an external power supply is off. Since flash memories are re-writable and re-erasable, they recently have been widely applied in the fabrication of electrical products, such as mobile phones, digital cameras, video players, personal digital assistants (PDA) or systems on a chip (SOC).

Flash memories include a plurality of memory units, and each memory unit includes a MOS (Metal-Oxide-Semiconductor) transistor for storing bit digital data. Please refer to FIG. 1, which is a cross sectional diagram illustrating a conventional flash memory cell. As shown in FIG. 1, the flash memory cell 10 includes a semiconductor substrate 12 and a gate stack 14 disposed on the semiconductor substrate 12. The gate stack 14 includes a floating gate 16 and a control gate 18. The floating gate 16 and the control gate 18 are commonly made of polysilicon, and the dielectric layer 20, an oxide layer for example, could be disposed between each of the gates for electric insulation. The flash memory cell 10 further includes a source region 22 and a drain region 24 disposed in the semiconductor substrate 12 at both sides of the gate stack 14, and a channel region 26 defined in the semiconductor substrate 12 between the source region 22 and the drain region 24. The detailed structure and the physical mechanism may be different between different types of flash memory units, however, when the flash memory 10 is selected to perform a programming operation (i.e. store data), it is common that an electric charge, such as electron, is injected into the floating gate 16 in order to change the threshold voltage of the flash memory cell 10. The value of the threshold voltage represents the stored data in the flash memory cell 10, which could be either 0 or 1. For example, the dielectric layers 20 between the floating gate 16 and the semiconductor substrate 12 may serve as a tunneling oxide layer, and the hot electrons through the dielectric layers 20 get in or out of the floating gate 16, thereby achieving data accessing of the flash memory cell 10.

In addition, if the flash memory cell 10 is selected to perform an erasing operation, the original stored data in the flash memory cell 10 needs to be erased, i.e. the stored electric charge of the floating gate 16 in the flash memory cell 10 should be removed. The electric charge of the floating gate 16 can be removed along the route 28 which goes from the floating gate 16 to the channel region 26, the route 30 which goes from the floating gate 16 to the source region 22, and the route 32 which goes from the floating gate 16 to the drain region 24. After the flash memory cell 10 has erased data along the same route several times, the dielectric layer 20 serving as a tunneling oxide on the route suffers damage and traps are formed therein. The electric charges may therefore be trapped without being removed, which may cause the flash memory cell 10 to become inactive. Consequently, how to improve the method of removing the stored electric charges in the floating gate in order to enhance the operation performance and endurance of the flash memory cell is still an important issue in the field.

### SUMMARY OF THE INVENTION

An objective of the present invention is therefore to provide a semiconductor device including a gate disposed in a shallow trench isolation (STI), wherein the gate has at least a protrusion, so as to improve the performances of the semiconductor device.

According to an exemplary embodiment of the present invention, a semiconductor device is provided. The semiconductor device includes a semiconductor substrate, at least a first gate, a shallow trench isolation (STI) and a third gate. The first gate is disposed on the semiconductor substrate, and the first gate partially overlaps the third gate and the shallow trench isolation. Furthermore, the third gate is disposed in a shallow trench isolation, and the third gate includes at least a protrusion.

According to another exemplary embodiment of the present invention, a semiconductor device is provided. The semiconductor device includes a semiconductor substrate, at least two first gates, a first shallow trench isolation (STI) and a third gate. The first gates are disposed on the semiconductor substrate, and each of the first gates partially overlaps the third gate. Furthermore, the third gate is disposed in the first shallow trench isolation, and the third gate includes at least a protrusion.

The protrusion of the third gate increases the overlapped area between the first gate and the third gate, and the route used for removing the stored electric charges in the first gate can thereby be increased. Furthermore, due to the disposition of the protrusion of the third gate, the stored electric charges in the first gate can be removed through the corner between the first gate and the third gate, which may shorten the time needed for erasing the electric charges. Accordingly, the disposition of the third gate including at least a protrusion can enhance the operation performance and endurance of the semiconductor device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross sectional diagram illustrating a conventional flash memory cell.

FIG. 2 illustrates a layout of a semiconductor device according to a first exemplary embodiment of the present invention.

FIG. 3 is a cross-sectional view taken along the line A-A′ of FIG. 2 illustrating a semiconductor device according to a first exemplary embodiment of the present invention.

FIG. 4 is a cross-sectional view taken along the line B-B′ of FIG. 2 illustrating a semiconductor device according to a first exemplary embodiment of the present invention.

FIG. 5 is a cross-sectional schematic diagram illustrating a semiconductor device according to a second exemplary embodiment of the present invention.

FIG. 6 is a cross-sectional schematic diagram illustrating a semiconductor device according to a third exemplary embodiment of the present invention.

FIG. 7 is a cross-sectional schematic diagram illustrating a semiconductor device according to a fourth exemplary embodiment of the present invention.

FIG. 8 is a cross-sectional schematic diagram illustrating a semiconductor device according to a fifth exemplary embodiment of the present invention.

FIG. 9 through FIG. 11 are schematic diagrams illustrating a method of fabricating a third gate according to a preferred exemplary embodiment of the present invention.

### DETAILED DESCRIPTION

To provide a better understanding of the present invention, preferred exemplary embodiments will be described in detail. The preferred exemplary embodiments of the present invention are illustrated in the accompanying drawings with numbered elements.

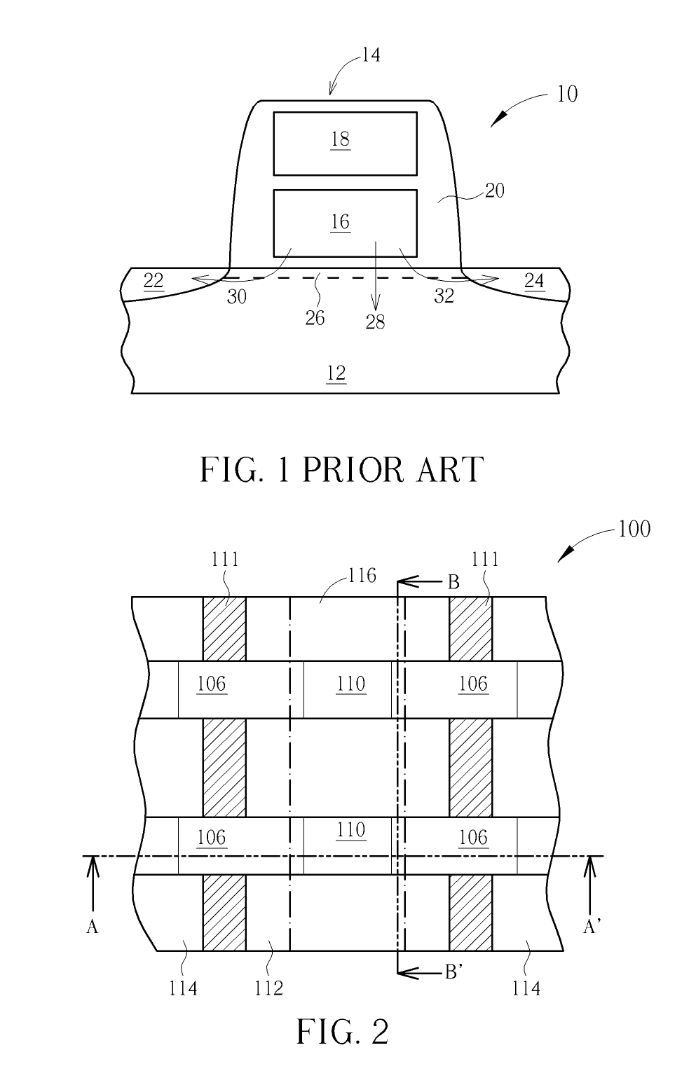

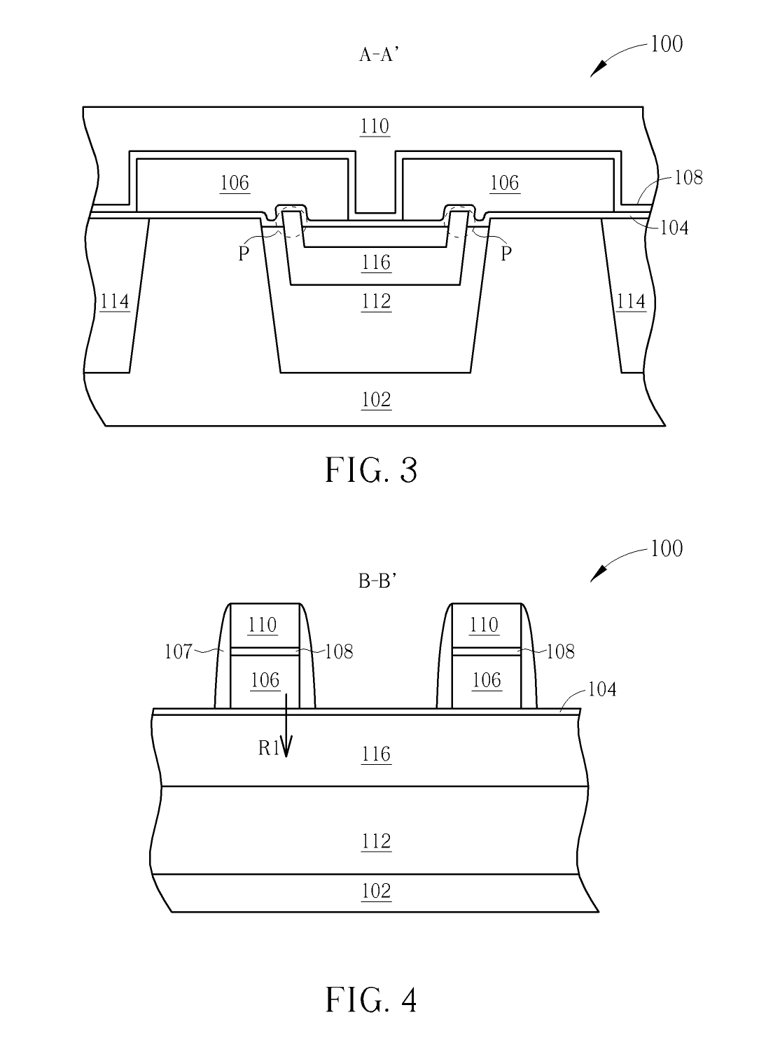

First, please refer to FIG. 2, FIG. 3 and FIG. 4. FIG. 2 illustrates a layout of a semiconductor device according to a first exemplary embodiment of the present invention. FIG. 3 is a cross-sectional view taken along the line A-A′ of FIG. 2 illustrating a semiconductor device according to a first exemplary embodiment of the present invention. FIG. 4 is a cross-sectional view taken along the line B-B′ of FIG. 2 illustrating a semiconductor device according to a first exemplary embodiment of the present invention. Furthermore, FIG. 2 is a top-view schematic diagram, wherein some components in FIG. 3 and FIG. 4 are not illustrated in order to clearly show the relative positions of the main components.

As shown in FIG. 2, FIG. 3 and FIG. 4. The semiconductor device 100 includes a first dielectric layer 104, at least two first gates 106, a second dielectric layer 108 and at least a second gate 110 sequentially disposed on a semiconductor substrate 102, a spacer 107 and a doped region 111. The semiconductor substrate 102 includes a substrate composed of Si, AsGa, silicon on insulator (SOI) layer, epitaxial layer, SiGe layer or other semiconductor materials. The first dielectric layer 104 and the second dielectric layer 108 may be made of dielectric materials such as silicon oxide, silicon oxynitride, or other high-k gate dielectric layers with a dielectric constant larger than 4. The first dielectric layer 104 can be formed through thermal oxidation process or deposition process such as chemical vapor deposition (CVD) process. The first dielectric layer 104 disposed between each of the first gates 106 and the semiconductor substrate 102 may serve as a tunneling oxide layer, and the hot electrons get in or out of the first gate 106 through the first dielectric layer 104, thereby achieving data access in the semiconductor device 100. Furthermore, the second dielectric layer 108 disposed between the first gate 106 and the second gate 100 may include a single layered structure or a multi-layered structure, like an oxide-nitride-oxide (ONO) stacked layer for example, or an inter-poly oxide (IPO) layer, in order to serve as an inter-gate dielectric layer for electric insulation. The spacer 107 made of dielectric material can provide insulation effect. Moreover, the first gates 106 and the second gate 110 may be made of conductive materials such as polysilicon, metal silicide or metal layer with specific work functions. When the semiconductor device 100 is a non-volatile memory cell for example, the first gate 106 may serve as a floating gate which can be used to store hot electrons, and the second gate 110 may serve as a control gate which can be used to control the data access function of the semiconductor device 100. In this exemplary embodiment, the second gate 110 simultaneously covers the two neighboring first gates 106, but not limited thereto.

The semiconductor device 100 further includes shallow trench isolations surrounding the doped region 111. The shallow trench isolations include a first shallow trench isolation (STI) 112 disposed in the semiconductor substrate 102 at a side of the first gate 106 and at least a second shallow trench isolation 114 disposed oppositely to the first shallow trench isolation 112, in other words, in the semiconductor substrate 102 at another side of the first gate 106. Each of the first gates 106 partially overlaps the first shallow trench isolation 112 and the second shallow trench isolation 114. The first shallow trench isolation 112 and the second shallow trench isolation 114 are commonly made of dielectric material such as silicon oxide, and as the shallow trench isolation processes are known to those skilled in the art, so the details are omitted herein for brevity. The shapes, locations and the order of formation of STIs are not limited. The sizes, the shapes and the arrangement layouts of the first shallow trench isolation 112 and the second shallow trench isolation 114 are not limited.

A third gate 116 having a non-planar top is disposed in the semiconductor substrate 102. More specifically, the third gate 116 is disposed in the first shallow trench isolation 112. The third gate 116 may be made of conductive materials such as polysilicon, metal silicide or metal layer with specific work functions. Each of the first gates 106 partially overlaps the third gate 116, which means that a part of the third gate 116 is located under each of the first gates 106, and a part of the third gate 116 is located between the two first gates 106. The second gate 110 simultaneously covers the two neighboring first gates 106, and the third gate 116 between the two first gates 106.

It is appreciated that the third gate 116 includes at least a protrusion P, wherein a top of the protrusion P is substantially between a top of the first shallow trench isolation 112 and a bottom of the first gate 106, and the top of the protrusion P is preferably substantially higher than an original surface of the semiconductor substrate 102, i.e. the surface of the semiconductor substrate 102 between the first shallow trench isolation 112 and the second shallow trench isolation 114, in other words, a top surface of the doped region 111. At least one of the first gates 106 partially overlaps the protrusion P, and the protrusions P of the same third gate 116 may be covered by the different first gates 106. The overlapped region between each of the first gates 106 and the third gate 116 therefore includes a top of the protrusion P, a part of a sidewall of the protrusion P, and two top angles of the protrusion P. In the conventional technology, the electric charges in the first gate are only released through the first dielectric layer i.e. the tunneling oxide layer extending along a horizontal direction, but in this exemplary embodiment, the two top angles of the protrusion P cause the formation of corners in the overlapped region between each of the first gates 106 and the third gate 116, and the stored electric charges in the first gate 106 can be rapidly removed through the corner to the third gate 116, which is beneficial for reducing the consumed time for removing the stored electric charges. Accordingly, the erasing operation of the semiconductor device 100 can be effectively completed. Additionally, when the semiconductor device 100 is a non-volatile memory cell for example, the third gate 116 may serve as an erase gate.

In this exemplary embodiment, as shown in FIG. 3 and FIG. 4, the third gate 116 includes two protrusions P respectively disposed under each of the first gates 106, and each of the first gates 106 partially overlaps the corresponding protrusion P; the first dielectric layer 104, which is disposed between the first gate 106 and the third gate 116 conformally overlaps the protrusions P. Furthermore, the third gate 116 is only disposed in the first shallow trench isolation 112 under a surface of the semiconductor substrate 102 between the two first gates 106, and the third gate 116 is not disposed in the second shallow trench isolation 114 under a surface of the semiconductor substrate 102 at two sides of the two first gates 106. A width of the second shallow trench isolation 114 is substantially smaller than a width of the first shallow trench isolation 112 along a direction parallel to the line A-A′.

The disposition of the protrusion P of the third gate 116 in the present invention is not limited to the illustrated embodiment. Other exemplar embodiments are illustrated below, and in order to simplify the explanation, the same components are referred by using the same numerals as before, and only the differences are discussed, while the similarities are not mentioned again

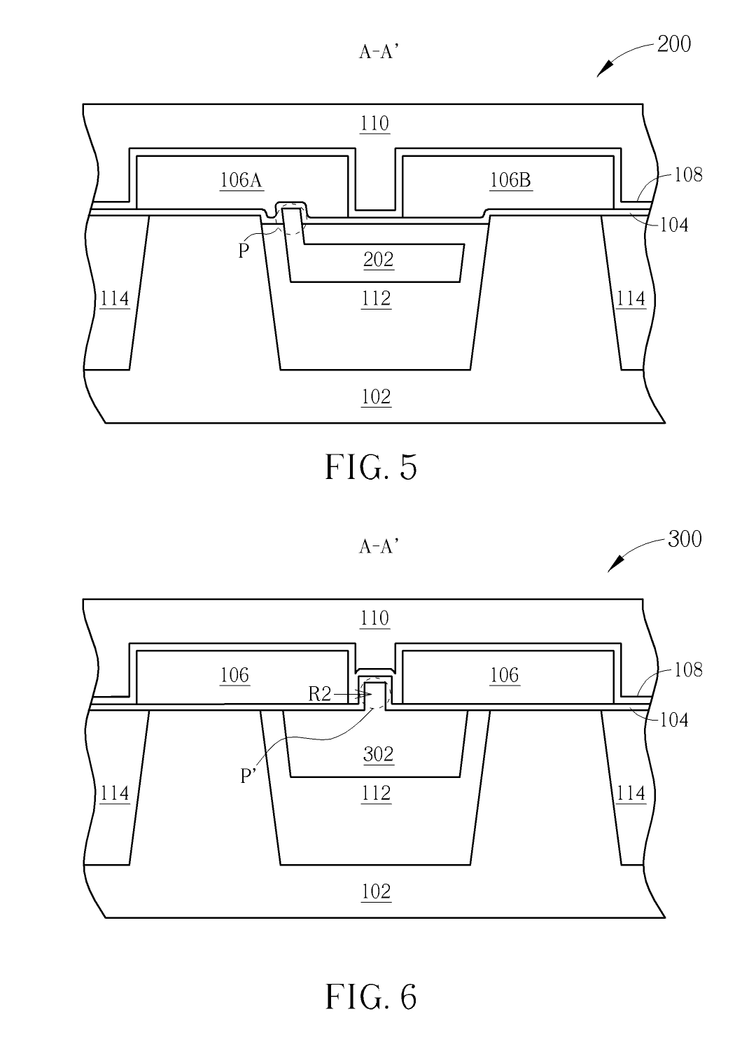

Please refer to FIG. 5, which is a cross-sectional schematic diagram illustrating a semiconductor device according to a second exemplary embodiment of the present invention. As shown in FIG. 5, a semiconductor device 200 includes the first shallow trench isolation 112 and the second shallow trench isolation 114 disposed in the semiconductor substrate 102, first gates 106A/106B disposed on the semiconductor substrate 102, and a third gate 202 disposed in the first shallow trench isolation 112. The main difference from the first exemplary embodiment is that the third gate 202 has only one protrusion P disposed under the first gate 106A, and no protrusion P is disposed under the first gate 106B. Accordingly, the efficiency of erasing electric charges in the two neighboring first gates 106A/106B may be different.

Please refer to FIG. 6, which is a cross-sectional schematic diagram illustrating a semiconductor device according to a third exemplary embodiment of the present invention. As shown in FIG. 6, a semiconductor device 300 includes a third gate 302 disposed in the first shallow trench isolation 112. Compared to the first illustrated exemplary embodiments, the main difference is that a protrusion P′ of the third gate 302 is disposed at a side of each of the first gates 106. More specifically, the protrusion P′ of the third gate 302 is disposed between the two first gates 1061, which means that the second gate 110 between the two first gates 106 may overlap the protrusion P′. Furthermore, a top of the protrusion P′ is substantially between the original surface of the semiconductor substrate 102 and the top of each of the first gates 106, i.e.: a part of the third gate 302 is in the semiconductor substrate 102, and a part of the third gate 302 (protrusion P′) is over the semiconductor substrate 102. The stored electric charges in the first gates 106 can not only be released through the first dielectric layer 104 extending along a horizontal direction such as the route R1 shown in FIG. 4, but also be released through the first dielectric layer 104 extending along a vertical direction such as the route R2 shown in FIG. 6 due to the disposition of the third gate 302 having a protrusion P′. Accordingly, the route used for removing the stored electric charges in the first gate 106 can thereby be improved.

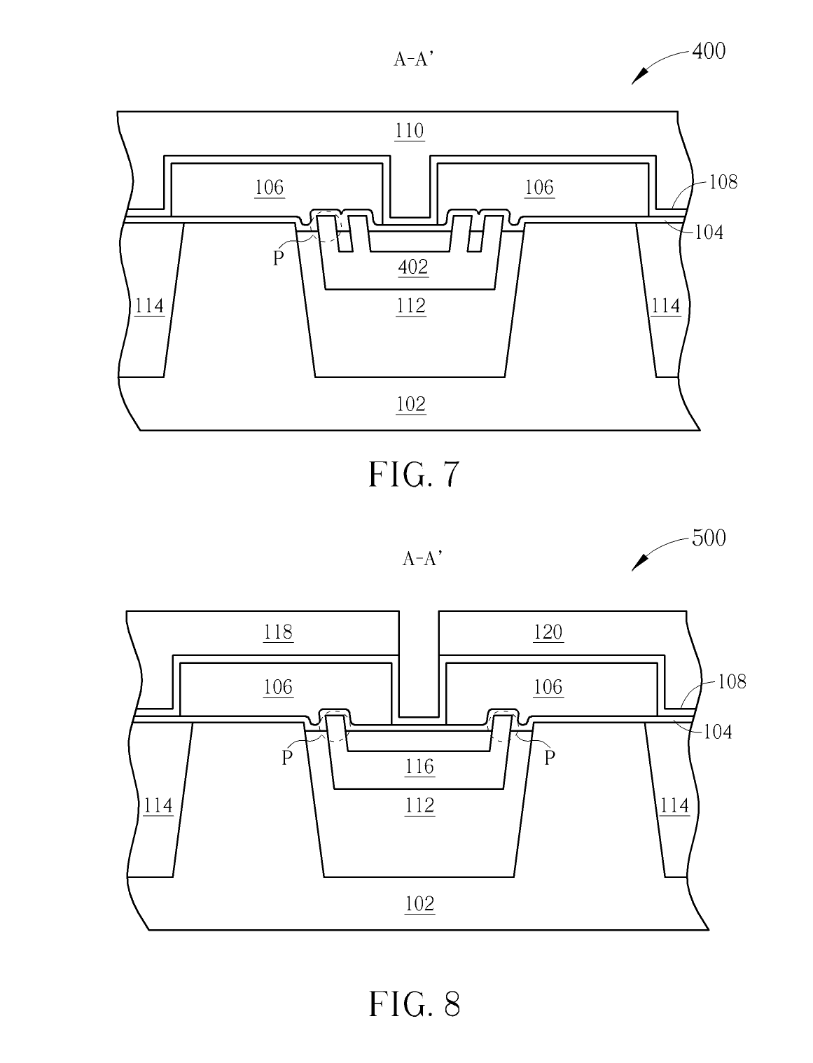

Please refer to FIG. 7, which is a cross-sectional schematic diagram illustrating a semiconductor device according to a fourth exemplary embodiment of the present invention. As shown in FIG. 7, a semiconductor device 400 includes a third gate 402 disposed in the first shallow trench isolation 112. The main difference from other exemplary embodiments is that each of the first gates 106 covers a plurality of the corresponding protrusions P of the third gate 402. In this exemplary embodiment, a plurality of protrusions P is arranged with a comb-shaped pattern along a direction parallel to the line A-A′, but not limited thereto. The protrusions P covered by one of the first gates 106 can be arranged in a comb-shaped pattern along a direction parallel to the line B-B′ as well. The disposition of the protrusions P may increase the routes used for releasing the stored electric charges in the first gates 106, and improve the date handling efficiency of the semiconductor device 400.

In other exemplary embodiments, a plurality of protrusions may be disposed under one first gate, and a lower number of protrusions, or no protrusion at all, may be disposed under the neighboring first gate, like in the second exemplary embodiment shown in FIG. 5. Furthermore, a plurality of protrusions may be disposed between two first gates along a direction parallel to the line B-B′, like in the third exemplary embodiment shown in FIG. 6. Moreover, a plurality of protrusions could be arranged under at least a first gate with a comb-shaped pattern along a direction parallel to the line B-B′, or a plurality of protrusions P could be arranged under at least a first gate 106 with a comb-shaped pattern simultaneously along a direction parallel to the line B-B′ and a direction parallel to the line A-A′. The size, the shape, the quantity and the arrangement of the protrusions of the third gate are not limited to the illustrated embodiments and can be modified according to the process requirements.

Please refer to FIG. 8, which is a cross-sectional schematic diagram illustrating a semiconductor device according to a fifth exemplary embodiment of the present invention. As shown in FIG. 8, the second gates 118/120 respectively cover the corresponding first gates 106 only, i.e. each of the second gates 118/120 may not overlap the substrate 102 and a part of the third gate 116 between the two neighboring first gates 106. Accordingly, the operation conditions applied to the second gates 118/120 may be different, like different operation voltages can be applied to the second gates 118/120 for example, so the electrically coupled voltage of the corresponding first gates 106 will be different, which is beneficial for the process flexibility of the semiconductor device 500. In this exemplary embodiment, the protrusions P of the third gate 116 are respectively under each of the first gates 106, the first dielectric layer 104 is disposed between the semiconductor substrate 102 and each of the first gates 106 and between each of the first gates 106 and the third gate 116, and the first dielectric layer 104 conformally covers the protrusions P. Similarly, the size, the shape, the quantity and the arrangement of the protrusions can be modified according to the process requirements.

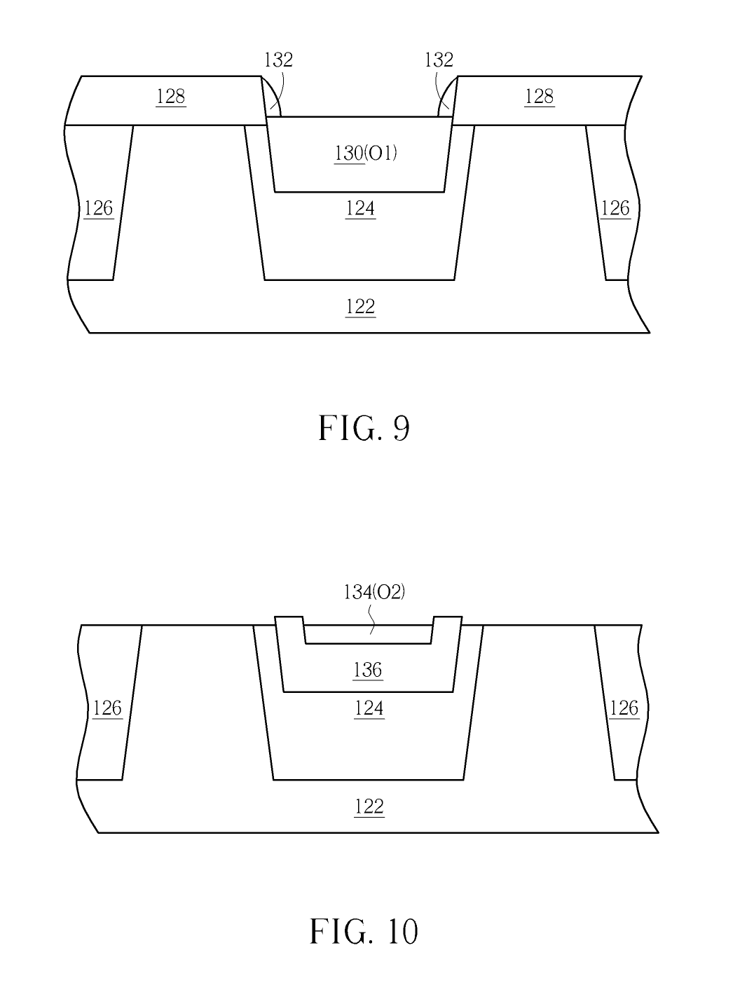

Please refer to FIG. 9 through FIG. 11, which are schematic diagrams illustrating a method of fabricating a third gate according to a preferred exemplary embodiment of the present invention. As shown in FIG. 9, a semiconductor substrate 122 is provided, and at least a shallow trench isolation is disposed in the semiconductor substrate 122. In this exemplary embodiment, the shallow trench isolations include a first shallow trench isolation 124 and a second shallow trench isolation 126 having different widths. Subsequently, a patterned mask 128 is formed on the semiconductor substrate 122, wherein the patterned mask 128 covers the second shallow trench isolation 126, and the first shallow trench isolation 124 is partially exposed.

An etching process is further performed to remove a part of the first shallow trench isolation 124, and a recess O1 is formed in the first shallow trench isolation 124. Then, a deposition process is performed to fill a conductive material layer (not shown) such as a polysilicon layer in the recess O1, and an etching back process is performed to remove a part of the conductive material layer to form the conductive layer 130 in the first shallow trench isolation 124. The thickness of the conductive layer 130 can be modified by the processing time of the etching back process according to the process requirements. In this exemplary embodiment, a top of the conductive layer 130 is higher than an original surface of the substrate 122, but not limited thereto: the top of the conductive layer could also be coplanar with the original surface of the substrate 122. Furthermore, a patterned spacer 132 used to define the pattern of the later formed protrusion is formed at the sidewall of the patterned mask 128, and the patterned spacer 132 covers a part of the conductive layer 130.

As shown in FIG. 10, the patterned mask 128 and the patterned spacer 132 may serve as a mask, and an etching process is performed to remove a part of the conductive layer 130, and a recess O2 is formed. Then, a deposition process is performed to fill a dielectric material layer (not shown), such as a silicon oxide layer in the recess O2, and an etching back process is performed to remove a part of the dielectric material layer to form the dielectric layer 134. Afterward, the patterned mask 128 and the patterned spacer 132 are removed. In this exemplary, a top of the dielectric layer 134 could be substantially aligned with the original surface of the substrate 122, but not limited thereto. Accordingly, the third gate 136 having protrusions is completed.

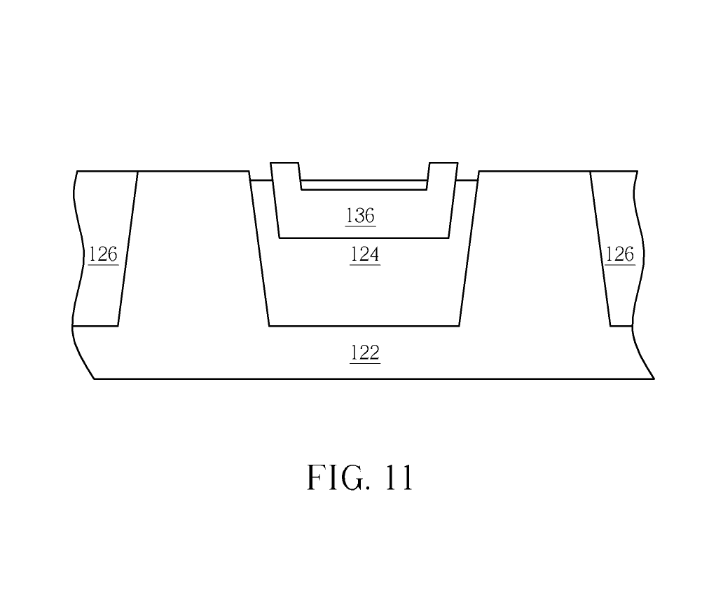

According to the process requirements, the following processes may be selectively performed. As shown in FIG. 11, a patterned mask (not shown) is formed on the semiconductor substrate 122, the patterned mask covers the second shallow trench isolation 126, and exposes the first shallow trench isolation 124, i.e. exposes the first shallow trench isolation 124, the dielectric layer 134 and the third gate 136. Then, an etching process is further performed to remove a part of the first shallow trench isolation 124, and the etchant preferably has selectivity to the dielectric material of the first shallow trench isolation 124 and the dielectric layer 134 such as silicon oxide. A part of the first shallow trench isolation 124 and a part of the dielectric layer 134 can therefore be removed, and a top of the protrusion of the third gate 136 can be much higher than a top of the first shallow trench isolation 124.

In addition, the first dielectric layer 104 can be formed on the semiconductor substrate 122 through thermal oxidation process or deposition process such as chemical vapor deposition (CVD) process. Furthermore, a first gate layer (not shown) made of conductive materials is formed through a low pressure chemical vapor deposition (LPCVD) process on the first dielectric layer 104. Afterwards, a patterned mask (not shown) such as a patterned photoresist layer is formed on the first gate layer, and an etching process is performed to remove a part oh the first gate layer in order to form the at least two first gates 106 separating from each other then the patterned photoresist layer is removed. Moreover, a second dielectric layer 108 and at least a second gate 110 are sequentially formed on the first gates 106 to complete the structure of semiconductor device similar to the semiconductor device 100 as shown in FIG. 2. In this exemplary embodiment, the first gates 106 may serve as floating gates, the second gate 110 may serve as a control gate, and the third gate 136 may serve as erasing gate.

In conclusion, the protrusion of the third gate increases the overlapped area between the first gate and the third gate, and the route used for removing the stored electric charges in the first gate can thereby be enhanced. Furthermore, due to the disposition of the protrusion of the third gate, the stored electric charges in the first gate can be removed through the corner between the first gate and the third gate, which may shorten the time needed for erasing the electric charges. Accordingly, the disposition of the third gate including at least a protrusion can improve the operation performances and endurance of the semiconductor device.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor device, comprising:
at least a first gate disposed on a semiconductor substrate; and
a third gate partially disposed in a shallow trench isolation (STI) and partially disposed on the shallow trench isolation, wherein the first gate partially overlaps the third gate and the shallow trench isolation, and the third gate comprises at least a protrusion.

2. The semiconductor device according to claim 1, wherein a top of the protrusion is substantially higher than a top of the shallow trench isolation.

3. The semiconductor device according to claim 1, wherein the shallow trench isolation is disposed in the semiconductor substrate, the protrusion is located under the first gate, and the first gate partially overlaps the protrusion.

4. The semiconductor device according to claim 1, wherein the protrusion is disposed at a side of the first gate.

5. The semiconductor device according to claim 4, wherein a top of the protrusion is substantially between an original surface of the semiconductor substrate and a top of the first gate.

6. The semiconductor device according to claim 1, further comprising:
a second gate;
a first dielectric layer disposed between the semiconductor substrate and the first gate; and
a second dielectric layer disposed between the first gate and the second gate.

7. The semiconductor device according to claim 6, wherein the first dielectric layer is disposed between the first gate and the third gate, and the first dielectric layer conformally covers the protrusion.

8. The semiconductor device according to claim 6, wherein the first gate comprises a floating gate, the second gate comprises a control gate, and the third gate comprises an erase gate.

9. A semiconductor device, comprising:
at least two first gates disposed on a semiconductor substrate; and
a third gate partially disposed in a first shallow trench isolation (STI) and partially disposed on the first shallow trench isolation, wherein each of the first gates partially overlaps the third gate, and the third gate comprises at least a protrusion.

10. The semiconductor device according to claim 9, further comprising at least a second shallow trench isolation disposed in the semiconductor substrate.

11. The semiconductor device according to claim 10, wherein each of the first gates partially overlaps the first shallow trench isolation and the second shallow trench isolation.

12. The semiconductor device according to claim 10, wherein the third gate is not disposed in the second shallow trench isolation.

13. The semiconductor device according to claim 12, wherein a width of the second shallow trench isolation is substantially smaller than a width of the first shallow trench isolation.

14. The semiconductor device according to claim 9, wherein a top of the protrusion is substantially higher than a top of the first shallow trench isolation.

15. The semiconductor device according to claim 9, wherein the first shallow trench isolation is disposed in the semiconductor substrate, and at least one of the first gates partially overlaps the protrusion.

16. The semiconductor device according to claim 9, wherein the protrusion is disposed between the two first gates, and a top of the protrusion is substantially between an original surface of the semiconductor substrate and a top of each of the first gates.

17. The semiconductor device according to claim 9, further comprising:
a second gate;
a first dielectric layer disposed between the semiconductor substrate and each of the first gates; and
a second dielectric layer disposed between each of the first gates and the second gate.

18. The semiconductor device according to claim 17, wherein the second gate covers the two first gates and the third gate.

19. The semiconductor device according to claim 17, wherein the first dielectric layer is disposed between each of the first gates and the third gate, and the first dielectric layer conformally covers the protrusion.

20. The semiconductor device according to claim 17, wherein each of the first gates comprises a floating gate, the second gate comprises a control gate, and the third gate comprises an erase gate.
